(19) United States
(12) Patent Application Publication
(10) Pub. No.: US 2019/0259579 A1
(43) Pub. Date: Aug. 22, 2019

(54) PLASMA ACTUATOR AND SURFACE CLEANING DEVICE

(71) Applicant: Kabushiki Kaisha Toshiba, Tokyo (JP)

(72) Inventors: Tomonao TAKAMATSU, Kawasaki (JP); Akio Ui, Tokyo (JP); Masato Akita, Kawasaki (JP)

(73) Assignee: Kabushiki Kaisha Toshiba, Tokyo (JP)

(21) Appl. No.: 16/111,628

(22) Filed: Aug. 24, 2018

(30) Foreign Application Priority Data
Feb. 19, 2018 (JP) 2018-26797

(51) Int. Cl. H01J 37/32; B08B 7/00

(52) U.S. Cl. CPC H01J 37/32568; B08B 7/0035; H01J 2237/335; H01J 37/32834; H01J 37/32055; H01J 37/32715

(57) ABSTRACT

According to one embodiment, a plasma actuator includes an electrode member, an application electrode, a ground electrode, and a supporting member. The electrode member has a first surface facing a processing object and a second surface of an opposite side of the first surface. The application electrode is provided in the first surface. The ground electrode is provided in the second surface or an inner portion of the electrode member. The supporting member is provided in at least one of the electrode member and the application electrode to form a processing space between the processing object and the electrode member. The supporting member is capable of abutting on the processing object.

### CROSS-REFERENCE TO RELATED APPLICATION

This application is based upon and claims the benefit of priority from Japanese Patent Application No. 2018-026797, filed on Feb. 19, 2018; the entire contents of which are incorporated herein by reference.

### FIELD

Embodiments described herein relate generally to a plasma actuator and a surface cleaning device.

### BACKGROUND

Examples of an active species generated by discharging in the atmosphere include negative ions such as OH radicals, ozone, and O²⁻. Among them, the OH radicals have a high redox potential of 2.80 ev, so that a purification capability to the air is large. However, the OH radicals are active but have a short life span. Therefore, there is considered a method of purifying the air or the like using the OH radicals contained in a water cluster.

A plasma induced flow is an air flow generated by applying a high voltage of a high frequency between electrodes which are separated by a dielectric. Plasma in the plasma induced flow draws an attraction as a new cleaning method instead of catalysis and an absorbent.

As a discharging structure for generating an active species, there is employed a point discharging structure and a mesh discharging structure. In addition, there is proposed a device in which electrodes generating the plasma induced flow are stacked and the air is taken in by the plasma induced flow so as to improve the processing efficiency.

However, in the method of the conventional technique, there is a need to secure a certain distance from a discharge point to a processing object. Therefore, there is a possibility that the OH radicals having 1 ms life span in the atmosphere (that is, a diffusion life of about several mm from the discharge point) is not possible to be effectively used. It cannot be said that the discharging structure of the conventional technique can effectively use the OH radicals with efficiency.

### BRIEF DESCRIPTION OF THE DRAWINGS

FIG. 1A is a perspective view of a surface cleaning device according to a first embodiment.

FIG. 1B is a cross-sectional view taken along line B-B′ of the surface cleaning device according to the first embodiment.

FIG. 2A is a perspective view of the surface cleaning device according to a second embodiment.

FIG. 2B is a perspective view taken along line B-B′ of the surface cleaning device according to the second embodiment.

FIG. 2C is a cross-sectional image view taken along line B-B′ of the surface cleaning device according to the second embodiment.

FIG. 3 is a cross-sectional image view of a first modification of the surface cleaning device according to the second embodiment.

FIG. 4 is a cross-sectional view illustrating a plurality of surface cleaning devices according to the second embodiment which are arranged along a processing object.

FIG. 5A is a cross-sectional view of the surface cleaning device according to a third embodiment.

FIG. 5B is a cross-sectional view in which a plurality of plasma actuators adjacently positioned are bonded using a connection member in the surface cleaning device according to the third embodiment.

FIG. 6A is a perspective view of the surface cleaning device according to a fourth embodiment.

FIG. 6B is an enlarged view of a cross section taken along line B-B′ of the surface cleaning device according to the fourth embodiment.

FIG. 6C is a cross-sectional view taken along line B-B′ of the surface cleaning device according to the fourth embodiment.

FIG. 7 is a cross-sectional image view of a first modification of the surface cleaning device according to the fourth embodiment.

FIG. 8A is a perspective view of a second modification of the surface cleaning device according to the fourth embodiment.

FIG. 8B is a cross-sectional view taken along line B-B′ of the second modification of the surface cleaning device according to the fourth embodiment.

FIG. 8C is a cross-sectional image view taken along line B-B′ of the second modification of the surface cleaning device according to the fourth embodiment.

FIG. 9A is a perspective view of the surface cleaning device according to a fifth embodiment.

FIG. 9B is a cross-sectional view taken along line B-B′ of the surface cleaning device according to the fifth embodiment.

FIG. 9C is a cross-sectional image view taken along line B-B′ of the surface cleaning device according to the fifth embodiment.

FIG. 10 is a perspective view of a first modification of the surface cleaning device according to the fifth embodiment.

### DETAILED DESCRIPTION

Hereinafter, the description will be given about a plasma actuator and a surface cleaning device according to embodiments with reference to the drawings. The components attached with the same symbol represent the same component. Further, the drawings are given schematically or conceptually, and a relation between thickness and width of the respective portions and a ratio coefficient of sizes between the portions may not be illustrated in the exactly actual size. In addition, even in a case where the same portion is illustrated, the dimension and the ratio coefficient may be differently illustrated in the drawings.

According to one embodiment, a plasma actuator includes an electrode member, an application electrode, a ground electrode, and a supporting member. The electrode member has a first surface facing a processing object and a second surface of an opposite side of the first surface. The application electrode is provided in the first surface. The ground electrode is provided in the second surface or an inner portion of the electrode member. The supporting member is provided in at least one of the electrode member and the application electrode to form a processing space between the processing object and the electrode member. The supporting member is capable of abutting on the processing object.

### First Embodiment

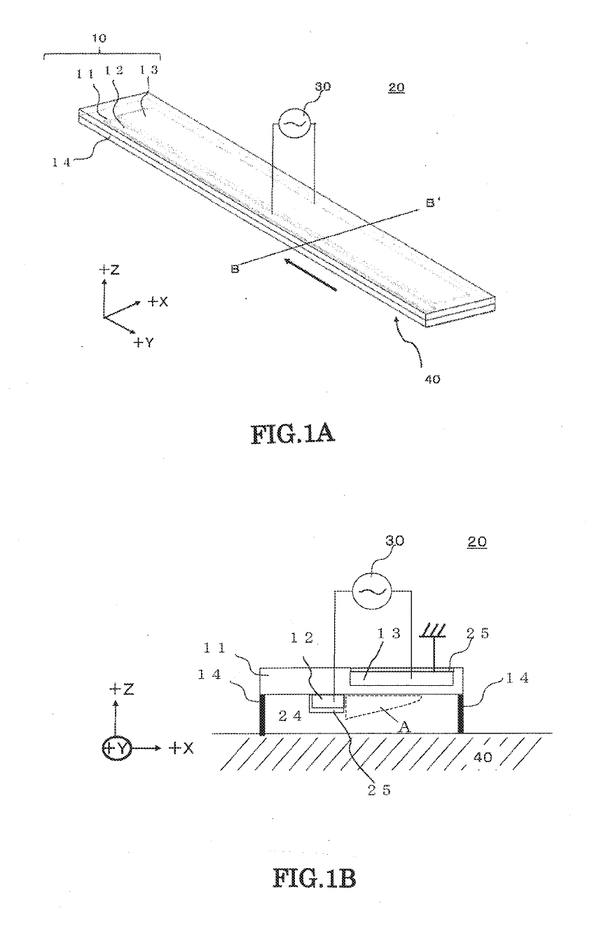

FIG. 1A is a perspective view of a surface cleaning device according to a first embodiment. FIG. 1B is a diagram illustrating a cross section taken along line B-B′ of the surface cleaning device according to the first embodiment when viewed from a direction of arrow. In FIG. 1B, the surface cleaning device is illustrated in a state of abutting on a processing object.

A surface cleaning device 20 includes a plasma actuator 10 and an AC power source 30.

As illustrated in FIG. 1B, when cleaning the surface of a processing object 40, the surface cleaning device 20 brings a supporting member 14 to abut on the processing object 40, and forms a processing space 24 between an electrode member 11 and the processing object 40.

The surface cleaning device 20 generates plasma in the processing space 24 (a plasma generating region A described below) to clean the surface of the processing object 40. The processing object 40 is preferably made of an insulating material such as resin, glass, or rubber.

Herein, for the convenience of explanation, +X direction, −X direction, +Y direction, −Y direction, +Z direction, and −Z direction will be defined. +X direction, −X direction, +Y direction, and −Y direction are directions substantially along the plane, for example. −X direction is a direction opposite to +X direction. In the embodiment, +X direction and −X direction represent “directions along the surface of the processing object”, for example. +Y direction is a direction intersecting with +X direction (for example, a direction which is substantially orthogonal). −Y direction is a direction opposite to +Y direction. +Z direction is a direction intersecting with +X direction and +Y direction (for example, a direction which is substantially orthogonal) and, for example, a direction substantially facing vertically upward. −Z direction is a direction opposite to +Z direction and, for example, a direction substantially facing vertically downward. As illustrated in FIG. 1B, −Z direction is a direction where the processing object 40 is located when viewed from the surface cleaning device 20. The defined coordinate axes are an example in a case where the surface of the processing object is placed on a horizontal plane, and can be appropriately applied according to a direction of the processing surface of the processing object.

First, the plasma actuator 10 will be described.

The plasma actuator 10 includes the electrode member 11, an application electrode 12, a ground electrode 13, and the supporting member 14. Further, in the explanation of the drawing, the supporting member 14 may be described separated from the plasma actuator 10.

The electrode member 11 is a dielectric substrate. The electrode member 11 is disposed, for example, along XY plane. In the electrode member 11, the application electrode 12 and the ground electrode 13 are provided. Examples of a material of the electrode member 11 include quartz, silicon rubber, and kapton (a type of polyimide). For example, the electrode member 11 is preferably about 0.5 mm thick, but the present embodiment is not limited thereto. The shape of the electrode member 11 is preferably an approximate cuboid, but may be formed in other shapes such as an approximate elliptical shape.

The application electrode 12 is disposed on a surface of the electronic member 11 (also referred to as a first surface) at a side in −Z direction of the electrode member 11 (that is, a surface facing the processing object). As illustrated in FIG. 1E, the application electrode 12 faces the processing object 40.

On a surface of the application electrode 12 at a side in direction of the application electrode 12, an insulating material 25 may be coated. Such a configuration is to prevent that the application electrode 12 is in contact with the processing object 40 and discharged.

The ground electrode 13 is disposed on a surface of the electronic member 11 (also referred to as a second surface) at a side in +Z direction of the electrode member 11. In other words, the electrode member 11 is located between the ground electrode 13 and the application electrode 12.

The expression “located between” means that the electrode member 11 is located in the middle between the application electrode 12 and the ground electrode 13 when viewed from +Z direction. In addition, this expression contains that the electrode member 11 is disposed to be interposed by the application electrode 12 and the ground electrode 13. In addition, if the application electrode 12, the electrode member 11, the ground electrode 13 are disposed in this order when viewed from −Z direction, this expression also contains that the application electrode 12 and the installation electrode 13 are disposed to be deviated in +X direction.

When viewing the application electrode 12 and the ground electrode 13 from −Z direction, an end of the ground electrode 13 in −X direction side is preferably disposed to be almost matched with an end of the application electrode 12 in +X direction side. In addition, a width of the ground electrode 13 in +X direction is preferably larger than a width of the application electrode 12 in X direction.

The ground electrode 13 has been described to be disposed on the surface of the electrode member 11, but may be disposed in an inner portion of the electrode member 11. In addition, a groove is provided in the electrode member 11, and the ground electrode 13 may be disposed at the groove.

The surface of the ground electrode 13 is coated with the insulating material 25. The insulating material 25 is a dielectric film to suppress a reverse discharge of the ground electrode 13. Examples of the insulating material 25 include a silicon oxide film, an organic insulating film, an insulating silicon filler, or a polyimide tape coating.

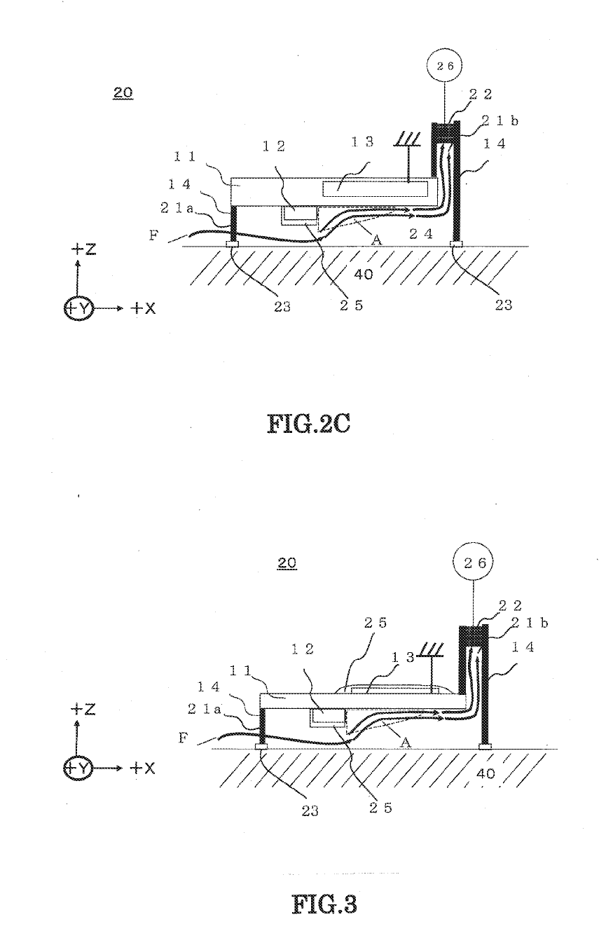

When the gas is brought into contact with the ground electrode 13, a reverse flow occurs due to the reverse discharge. Therefore, a plasma induced flow F (described below) may be suppressed, or an abnormal discharge (overheat) may occur in a fine space. In order to suppress these problems, the surroundings of the insulating material 25 are desirably coated with the insulating material 25. Note that the insulating material 25 coating the ground electrode 13 will be omitted except FIG. 1B and FIG. 3 described below.

The application electrode 12 and the ground electrode 13 are configured by a conductor such as metal. For example, a metallic material such as aluminum, brass, copper, or stainless steel may be used. The application electrode 12 and the ground electrode 13 may be formed as a thin gold (Au) film on the electrode member 11 by sputtering or plating for example.

The application electrode 12 and the ground electrode 13 are illustrated only by one, but the application electrode 12 and the ground electrode 13 may be provided in plural. The shape of the application electrode 12 and the ground electrode 13 is not limited to the approximate rectangular shape as illustrated in FIG. 1A. The shape may be formed in an approximate elliptic shape, and may be appropriately changed.

The supporting member 14 is disposed in any position which does not hinder the plasma from being generated. For example, the supporting member may be disposed on a surface of the electrode member 11 at a side in −Z direction, a side surface of the electrode member 11, or a surface of the application electrode 12 or the like. As illustrated in FIG. 1B, a tip end of the supporting member 14 is in a state of abutting on the processing object 40. The supporting member 14 prevents that the application electrode 12 is brought into contact with the processing object 40. In other words, the supporting member 14 keeps a distance from the application electrode 12 to the processing object 40 to be a predetermined distance, and forms the processing space 24 between the electrode member 11 and the processing object 40. The supporting member 14 is disposed to protrude in −Z direction compared to the application electrode 12. The supporting member 14 is preferably provided to surround the side surface of the application electrode 12 in X and Y directions. The expression “to surround” contains that the supporting member 14 is disposed at a predetermined distance in X and Y directions from the application electrode 12. In addition, the supporting member 14 is formed integrally, but the present embodiment is not limited thereto. For example, a plurality of supporting members may be disposed at a predetermined distance from the application electrode 12 in XY plane.

The supporting member 14 does not need to be integrally formed to the electrode member 11 and the application electrode 12 which abut on the supporting member 14, as long as there is no gap between the electrode member 11 and the application electrode 12. For example, the supporting member 14 may be formed using a screw with respect to the electrode member 11 and the application electrode 12, or may be sealed with silicon.

As a material of the supporting member 14, an insulating material such as resin and rubber is preferably used. A portion where the supporting member 14 abuts on the processing object 40 is preferably formed using a soft insulating material such as rubber and silicon in order to prevent a generated active species from leaking out of the processing space 24. In addition, the supporting member 14 at a side near the processing object and the opposite side of the supporting member 14 may be formed using different insulating materials. In addition, if the generating active species does not leak out of the processing space 24, there may be provided a member in a portion where the supporting member 14 and the processing object 40 abut.

In addition, the supporting member 14 may be stretchable in Z direction. In this case, there may be provided a motor, a slide rail, a pneumatic cylinder or the like to drive the supporting member 14 in Z direction. A distance between the application electrode 12 and the processing object 40 can be adjusted by stretching the supporting member 14. The supporting member 14 has been described as a configuration of the plasma actuator 10. However, the supporting member may be not included in the configuration of the plasma actuator 10.

The AC power source 30 is electrically connected to the application electrode 12 and the ground electrode 13, and applies an AC voltage between the application electrode 12 and the ground electrode 13.

Next, an operation of the surface cleaning device 20 will be described in detail.

First, the surface cleaning device 20 brings the supporting member 14 to abut on a target surface of the processing object 40. The bringing of the supporting member 14 to abut on the target surface may be performed manually by a user, or may be performed using a drive device such as a manipulator.

Next, the high-voltage AC power source 30 of the surface cleaning device 20 applies an AC high voltage (for example, 6 kV sinusoidal voltage of 10 kHz) between the application electrode 12 and the ground electrode 13.

When the AC voltage is applied, Plasma A is generated in a region depicted by a broken line of FIG. 1B. This is because the air near the application electrode 12 is ionized when the AC high voltage is applied between the application electrode 12 and the ground electrode 13. At this time, a distance between the application electrode 12 and the processing object 40 is preferably greater than 0 mm and equal to or less than 10 mm. With the configuration, the active species such as OH radicals and ozone generated by Plasma A efficiently acts on the processing object 40. In order to cause the OH radicals to act on the processing object with more efficiency, the distance is preferably set to 1 mm or more and 3 mm or less. In a case where the supporting member 14 is stretchable, the supporting member 14 may be driven to appropriately adjust the distance between the application electrode 12 and the processing object 40 after the supporting member 14 abuts on the processing object 40.

As illustrated in FIG. 1B, Plasma A is generated from an end of the application electrode 12 at a side in +X direction. Therefore, the width in Z direction of Plasma A and the region of Plasma A can be adjusted according to the thickness of the application electrode 12. In order to widen a generation region of Plasma A, the width of the application electrode 12 in Z direction may be set large enough not to be brought into contact with the processing object 40. In addition, as described above, the width of the ground electrode 13 in X direction is preferably larger than the width of the application electrode 12. With this configuration, the width of Plasma A in X direction becomes larger. Therefore, the generation amount and the region of the active species such as OH radicals are increased.

In the surface cleaning device 20 according to the present embodiment, the application electrode 12 is disposed to face the processing object, so that Plasma A can be generated near the processing object. Therefore, the OH radicals having an oxidization performance stronger than ozone but a short life span can act on the processing object with efficiency.

In the surface cleaning device 20 according to the present embodiment, the plasma actuator 10 includes the supporting member 14 abutting on the processing object as illustrated in FIG. 1A. Therefore, it is possible to provide the application electrode 12 to face the processing object. As a result, when the AC high voltage is applied between the application electrode 12 and the ground electrode 13 by the AC power source 30, and when the air near the application electrode 12 is ionized to generate plasma (Plasma A), Plasma A can directly act on the processing object since the application electrode 12 is disposed near the processing object. With this configuration, in the surface cleaning device according to the present embodiment, the OH radicals having a short life span included in Plasma A can directly act on the processing object, and the processing object can be cleaned with efficiency.

Note that the surface cleaning device according to the present embodiment has been described such that the AC power source is provided in the plasma actuator 10 equipped with the supporting member 14. However, the plasma actuator 10 may be not provided with the supporting member 14.

This component will be explained using FIGS. 1A and 18. The surface cleaning device 20 equips the plasma actuator 10, the supporting member 14, and the AC power source 30. The Plasma actuator 10 includes the electrode member 11, the ground electrode 13 provided in the electrode member 11, and the application electrode 12 disposed on a surface facing the processing object 40 in such a way as to interpose the electrode member 11 between the ground electrode 13 and the application electrode 12. The supporting member 14 forms the processing space 24 between the plasma actuator 10 and the processing object 40, which is capable of abutting on the plasma actuator 10 and the processing object 40. The AC power source 30 applies an AC current to the application electrode 12 and the ground electrode 13.

### Second Embodiment

The common components as those of the first embodiment will be omitted.

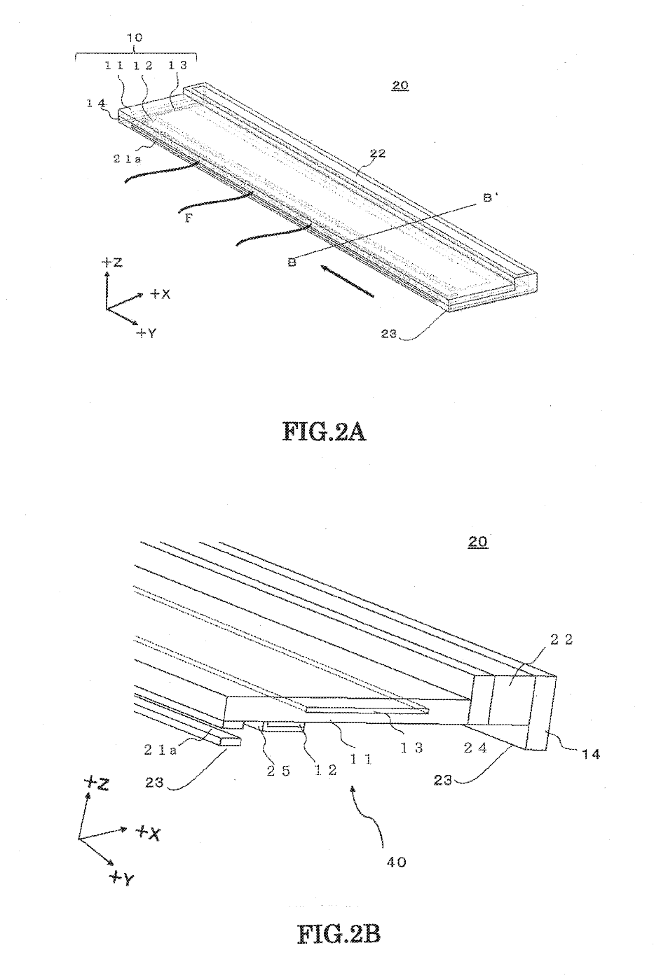

FIG. 2A is a perspective view of the surface cleaning device 20 according to a second embodiment. FIG. 2B is a perspective view of a cross section of the surface cleaning device 20 taken along line B-B′. FIG. 2C is a cross-sectional view taken along line B-B′ of the surface cleaning device 20 when viewed from a direction of arrow. Further, the AC power source except for FIG. 2A will be omitted.

The surface cleaning device of the present embodiment includes a conduction checking electrode 23, a through hole 21, an ozone processing unit 22, and an exhaust pump 26, in addition to the surface cleaning device according to the first embodiment.

The conduction checking electrode 23 is provided in a portion where the supporting member 14 and the processing object 40 abut. With the conduction checking electrode 23, it is possible to check an insulation state of a processing target surface. The processing target surface is a surface of the processing object 40 facing the surface cleaning device. If the current applied to the application electrode 12 is prevented from flowing to the processing object 40, the plasma is hardly generated. Therefore, since the processing target surface is required to be insulated in principle, it is preferably to include the conduction checking electrode 23. The conduction checking electrode 23 may have a mechanism which stops the operation of the surface cleaning device.

Even if the processing object 40 is made of metal or in a conduction state, the processing object 40 can be used as long as satisfying following conditions:

The processing target surface does not fall to the ground (ground potential);

A distance between the application electrode 12 and the processing target surface (held by the supporting member 14) is larger than a distance between the application electrode 12 and the ground electrode 13;

The processing target surface is coated to be insulated, and thus the plasma is generated on a side of the ground electrode instead of a side of the processing target surface.

The surface cleaning device of the present embodiment may include a reception unit (not illustrated) which receives a signal of the conduction checking electrode 23. With the reception unit, the conduction checking electrode 23 can cause the reception unit to receive a signal indicating that the processing target surface is a conductor or an insulator. In a case where the processing target surface is indicated as a conductor, the operation of the surface cleaning device 20 can be stopped by transmitting a signal from the reception unit to a user or by connecting the reception unit to the power source of the surface cleaning device 20.

The through hole 21 is provided in the supporting member 14. With the through hole 21, as illustrated in FIGS. 2A and 2C, in a case where the processing space 24 is separated from the supporting member 14, the external air and the air inside the processing space 24 can be exchanged. For example, when a through hole 21a is provided in the supporting member 14 existing in −X direction, the external air can be taken into the processing space 24. Therefore, it is possible to increase the generation amount of the OH radicals in Plasma A. Furthermore, if a through hole 21b is provided even in the supporting member 14 existing in +X direction from the application electrode 12, not only the processing object near Plasma A but also the gas in Plasma A can be moved by the plasma induced flow F (described below). Therefore, it is possible to process the processing object over a wide range.

Furthermore, the gas moved by the plasma induced flow F can be moved from the processing space 24 to the outer side through the through hole 21b which is provided in the supporting member 14 existing in +X direction. Therefore, it is possible to easily take the air into the processing space 24 from the outer side.

The shape of the through hole 21 can allow the through hole 21a provided in the supporting member 14 in −X direction to pass through in one square shape as illustrated in FIGS. 2A and 2B, and also allow a plurality of square shapes to pass through in parallel. Furthermore, at the downstream side (+X direction) of the plasma induced flow F, the through hole 21a provided in the supporting member 14 in −X direction is formed in one square shape. This through hole can also be made smaller toward a side in +X direction such that the through hole 21a becomes narrower from the middle of the supporting member 14 in −X direction. In addition, the through hole 21 may be formed in an L shape toward a side in +Z direction from −X direction of the through hole 21b provided in the supporting member 14 existing in +X direction. Furthermore, a plurality of through holes 21 may also be provided. Likewise, the shape may be appropriately changed.

The ozone processing unit 22 may be equipped in the inner portion of the through hole 21 provided at the downstream side (+X direction) of the plasma induced flow F. Furthermore, the ozone processing unit 22 may be connected to the through hole 21, and thus provided on the outer side of the surface cleaning device. In the plasma discharge in the atmosphere, ozone is considerably generated. Therefore, in a device such as a surface processing device or a sanitizer using discharge, the ozone is needed to be separated normally in order not to affect on human bodies. However, with the ozone processing unit 22, the active species such as ozone and oxygen can be limited not to diffuse into the atmosphere.

The ozone processing unit 22 may also be configured to connect with the exhaust pump 26. The exhaust pump 26 can suck the gas in the processing space 24 through the ozone processing unit 22, and can discharge the gas into the outer side. Therefore, the ozone in the processing space 24 can be processed with efficiency. In addition, with the exhaust pump 26, it is possible to assist a flow of the plasma induced flow F. Therefore, the active species such as the OH radicals can act far away from the Plasma A. Since the gas in the processing space 24 can be discharged to the outer side, the air of the outer side can be supplied much more through an inlet port. As a result, it is possible to increase the generation of the OH radicals with more efficiency.

### First Modification

FIG. 3 is a diagram illustrating a modification of the surface cleaning device according to the second embodiment. In the diagram of the surface cleaning device 20, the ground electrode 13 is not provided in the inner portion of the electrode member 11, but provided in the surface of the electrode member 11 in +Z direction. The ground electrode 13 is coated with the insulating material 25. With such a configuration, the surface cleaning device 20 can be used even if a groove is not provided in the electrode member 11.

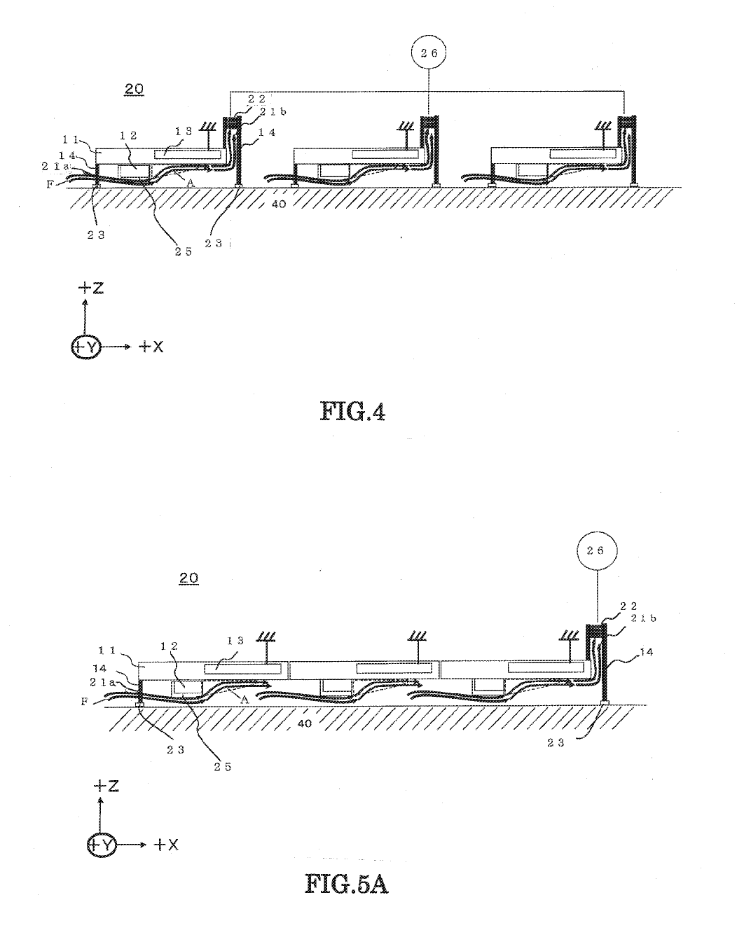

FIG. 4 is a cross-sectional view illustrating a plurality of surface cleaning devices according to the second embodiment, in which the surface cleaning devices are aligned along the processing object. As illustrated in FIG. 4, in a case where the plurality of surface cleaning devices according to the second embodiment is aligned in +X direction, a wide range of the processing object can be processed at a time. At this time, the exhaust pump 26 may be provided in each surface cleaning device. Alternatively, one exhaust pump 26 may be shared thereby. Even in a case where the conduction checking electrode 26 and the reception unit are provided, these components may be attached to each surface cleaning device, or shared thereby. In addition, the components may be aligned in Y direction similarly. Even at this time, the exhaust pump 26, the conduction checking electrode 23, and the reception unit may be connected in a similar way. The surface cleaning device according to the present embodiment can be used to clean structures such as a desk, a chair, a floor, and a wall. In addition, when being used, the surface cleaning device according to the present embodiment may be moved by the user or may be self-operated. When the user moves the surface cleaning device, the surface cleaning device may be operated at a remote place using a remote controller. At this time, a reception device such as the remote controller or the like may be provided at a position not hindering the operation of the surface cleaning device.

When the surface cleaning device according to the present embodiment is operated, Plasma A and the plasma induced flow F can be generated. A mechanism of generating the plasma induced flow F will be conceptually described using FIG. 2C.

Plasma A is generated from a ground electrode side of the application electrode 12 on the surface of the electrode member 11 in a direction of the ground electrode 13 by the AC high voltage from the high-voltage AC power source 30. The plasma A contains positive ions and electrons. The positive ions flow from the application electrode 12 in the direction of the ground electrode 13 on the surface of the electrode member 11. This flow comes into conflict with the atmosphere to generate the plasma induced flow F together with the gas stream surrounding the flow.

The electrons are accumulated on the surface of the electrode member 11 abutting on Plasma A to charge up the surface negatively. Therefore, the positive ions evenly flow in a direction on the surface of the electrode member 11 corresponding to a direction from the application electrode 12 to the ground electrode 13. Since the generated Plasma A is a thin surface plasma, the plasma induced flow F also becomes a surface stream which flows near the electrode member 11. In other words, by disposing the ground electrode 13 in a certain direction deviated from the application electrode 12, the plasma induced flow F flowing in the certain direction is generated.

As illustrated in FIG. 2C, when the AC high voltage is applied between the application electrode 12 and the ground electrode 13 by the AC power source 30, the air is ionized near the application electrode 12, and the plasma is generated. With this configuration, the plasma induced flow F is generated from the application electrode 12 in the processing space 24 to flow from the through hole 21a of the supporting member 14 existing in −X direction toward the through hole 21b of the supporting member 14 existing in +X direction. At this time, the application electrode 12 faces near the processing object, so that the plasma induced flow F can progress in a direction along the surface of the processing object. Therefore, it is possible to use the OH radicals contained in the Plasma A (moved by the plasma induced flow F) directly to the processing object in a wide range. As a result, it is possible to provide the surface cleaning device capable of cleaning the processing object with high efficiency.

Further, in the present embodiment, the surface cleaning device has been described to include all the conduction checking electrode 23, the through hole 21, the ozone processing unit 22, and the exhaust pump 26. In addition, only the conduction checking electrode 23 may be provided, or only the through hole 21 may be provided. Likewise, the configuration may be appropriately selected. For example, in the surface cleaning device including the through hole 21 only in the supporting member 14 on a side near the application electrode (−X direction), the active species may be used to stay in the processing space 24. In addition, the ozone processing unit 22 has been provided in consideration of an influence on human bodies. However, the ozone processing unit 22 may be not provided under an environment where there is no need to consider such the influence.

### Third Embodiment

The same portions as those of the second embodiment will be omitted.

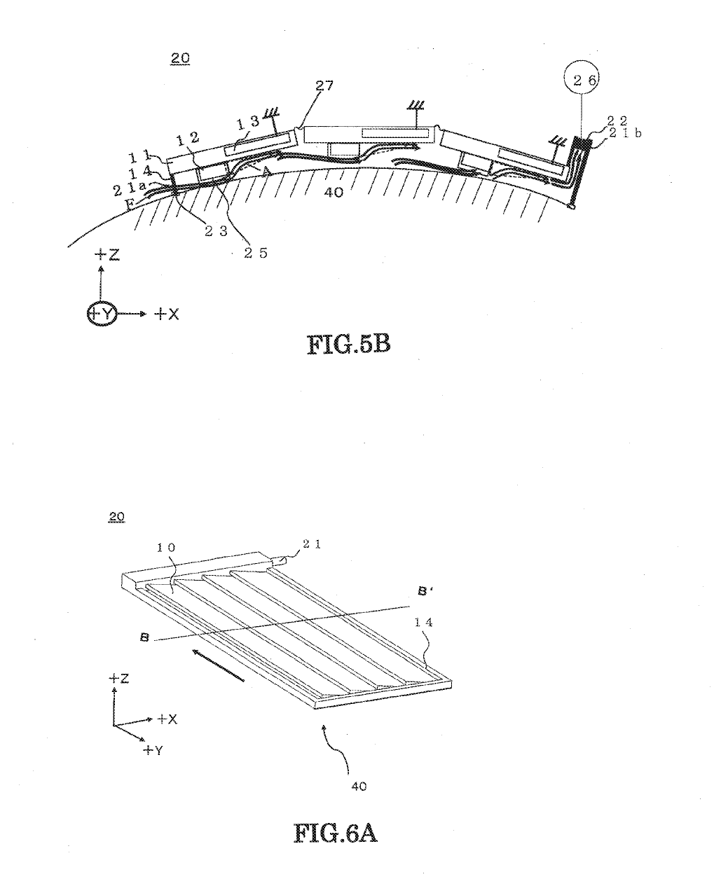

FIG. 5A is a cross-sectional view of the surface cleaning device according to a third embodiment. FIG. 5B is a cross-sectional view in which a plurality of plasma actuators adjacently positioned in the surface cleaning device according to the third embodiment are bonded using a connection member.

In the surface cleaning device according to the third embodiment, two or more plasma actuators described in the first embodiment are aligned along the processing object. A distance between the application electrode 12 and the ground electrode 13 of one plasma actuator 10 is shorter than a distance between the application electrode 12 (of one plasma actuator) and the ground electrode 13 (of another plasma actuator adjacent to the one plasma actuator). The processing spaces 24 of the plasma actuators 10 adjacently positioned are disposed continuously. In addition, as illustrated in FIG. 5B, the plasma actuators 10 adjacently positioned can make the processing spaces 24 continue using a connection member 27.

The distance between the application electrode 12 and the ground electrode 13 is a distance between the closest ends thereof. For example, the distance is a distance connecting a portion of the application electrode 12 at a side near the ground electrode 13 and nearest to the ground electrode 13, and a portion of the ground electrode 13 at a side near the application electrode 12 and nearest to the application electrode 12. The configuration is similar even in a single surface cleaning device, or even between two or more surface cleaning devices.

The plasma induced flow F can flow serially among the plasma actuators 10 (adjacently positioned) by connecting the processing spaces 24 thereof. With this configuration, the processing space 24 can be made in a simple shape, and a sealing level of the processing space 24 can be increased. As a result, it is possible to suppress the active species from leaking out to the outer side on the way of flowing, and a concentration of the active species can be secured. At this time, the supporting member 14 of the plasma actuators 10 (adjacently positioned) in +X direction may not exist as illustrated in FIG. 5A, or may exist partially. In addition, one exhaust pump 26 may be shared thereby. In addition, in a case where the conduction checking electrode 23 is provided, the conduction checking electrode 23 may be attached to each supporting member 14, or may be shared thereby.

In addition, as illustrated in FIG. 5B, the surface cleaning devices 20 may be disposed along a curved surface of the processing object by using a deformable connection members 27. Therefore, the curved surface of the processing object can be cleaned. Even at this time, the supporting member 14 (of the plasma actuators 10 adjacently positioned) in +X direction may not exist, or may exist partially.

The surface cleaning device according to the third embodiment may be used to clean structures such as a desk, a chair, a floor, and a wall similarly to the surface cleaning according to the second embodiment. Furthermore, the surface cleaning device according to the third embodiment may also be used to clean a structure having a curved surface such as a ball. In addition, when being used, the surface cleaning device according to the third embodiment may be moved by the user or may be self-operated. When the user moves the surface cleaning device, the surface cleaning device may be operated at a remote place using a remote controller or the like. At this time, a reception device of the remote controller or the like may be provided at a position not hindering the operation of the surface cleaning device.

In the surface cleaning device according to the third embodiment, the application electrode 12 can be disposed near the processing object 40. Therefore, it is possible to use an active species having a short life span such as the OH radicals contained in Plasma A. In addition, the surface cleaning device can be provided in a wider range, and the active species can be suppressed from leaking out to the outer side. As a result, it is possible to provide the surface cleaning device capable of cleaning the processing object with more efficiency.

### Fourth Embodiment

The same portions as those of the second embodiment will be omitted.

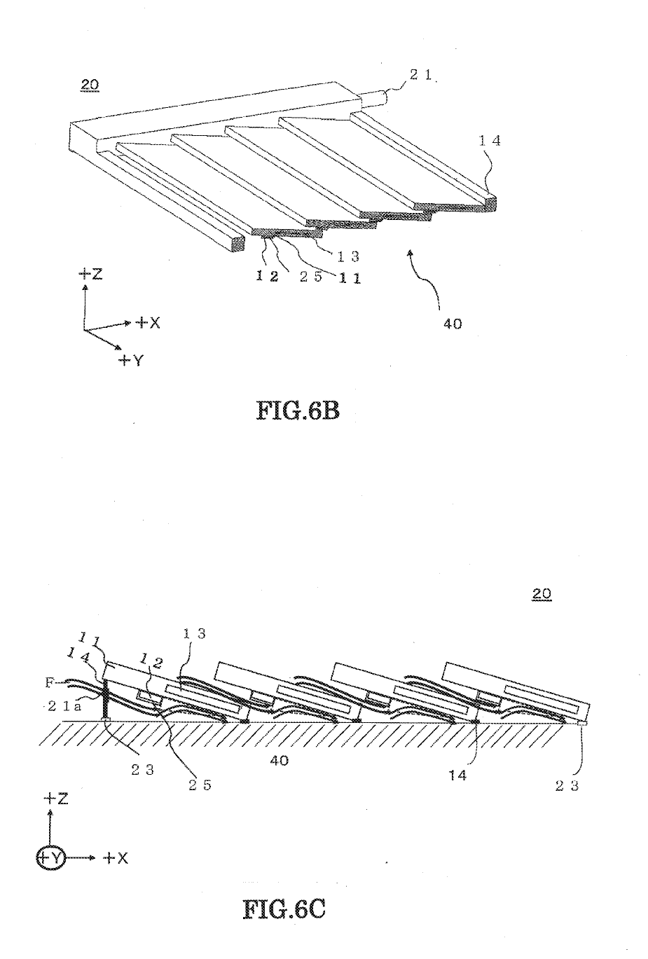

FIG. 6A is a perspective view illustrating the surface cleaning device according to a fourth embodiment. FIG. 6B is an enlarged view of a cross section taken along line B-B′ of FIG. 6A. FIG. 6C is a diagram illustrating a cross section taken along line B-B′ of FIG. 6A when viewed from a direction of arrow (+Y direction). The surface cleaning device according to the fourth embodiment is configured such that the plasma actuator 10 described in the first embodiment is inclined to bring the ground electrode side (+X direction) near the processing object (−Z direction). In addition, the plasma actuators adjacently positioned are disposed to be partially overlapped. Furthermore, the surface cleaning device is configured such that a distance between the application electrode 12 and the ground electrode 13 of one plasma actuator 10 is shorter than a distance between the application electrode 12 of one plasma actuator and the ground electrode 13 of another plasma actuator adjacent to the one plasma actuator. The connection members 27 may be provided between the plasma actuators 10 for connection.

Since the distance between the application electrode 12 and the ground electrode 13 of one plasma actuator 10 is shorter than the distance between the application electrode 12 of one plasma actuator and the ground electrode 13 of another plasma actuator adjacent to the one plasma actuator, the plasma induced flow F cannot be reversely flown in the surface cleaning device. Description of this distance is the same as the third embodiment.

As illustrated in FIG. 6A, the plasma actuators 10 equips the supporting member 14 in Y direction. Therefore, a gap may be provided to be interposed between the plasma actuators 10 adjacently positioned. With the gap, the atmosphere can be taken into the plasma actuator 10 from the outer side. As a result, it is possible to keep the amount of the generated OH radicals. In addition, the electrode members 11 of the plasma actuators 10 adjacently positioned, or the electrode member 11 and the application electrode 12 thereof, can be directly overlapped.

The supporting member 14 provided in +X direction of the plasma actuator 10 is preferably provided such that the plasma actuator 10 and the processing object 40 do not directly abut on each other.

In the surface cleaning device according to the fourth embodiment, the plasma actuators 10 adjacently positioned is disposed to partially overlap, so that the operation region of the OH radicals can be dense with respect to the processing object. As a result, it is possible to clean the processing object with efficiency.

As illustrated in FIG. 6C, since the supporting member 14 of the plasma actuator 10 is provided in +X direction, the processing spaces 24 of the plasma actuators 10 adjacently positioned may be not disposed serially. In this case, the plasma induced flow F generated in each of the plasma actuators 10 flows in +X direction. The plasma induced flow F flows in a direction (Y direction) along the supporting member 14 provided in +X direction of each plasma actuator 10. Therefore, as illustrated in FIG. 6B, by providing the through hole 21 connecting to the outer side in at least one of the supporting members 14 existing in parallel with a flowing direction of the plasma induced flow F, the gas moved by the plasma induced flow F can be moved from the processing space 24 to the outer side. Accordingly, the air can be easily taken into the processing space 24 from the outer side.

Furthermore, the ozone processing unit 22 may be provided in the through hole 21. In addition, the exhaust pump 26 may be connected to the ozone processing unit 22.

### First Modification

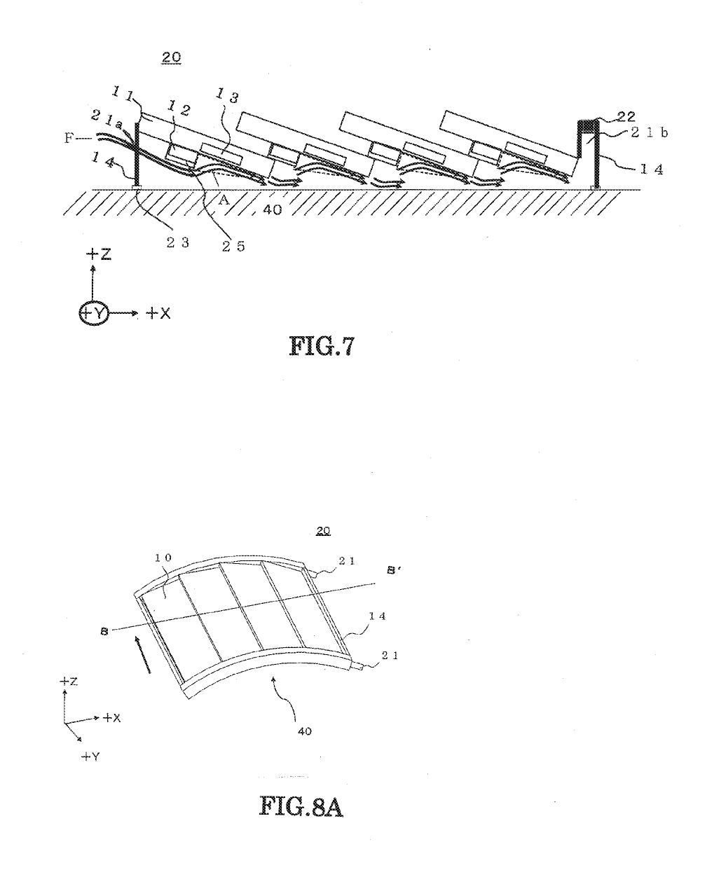

FIG. 7 is a cross-sectional image view of a first modification of the surface cleaning device according to the fourth embodiment. As illustrated in FIG. 7, the electrode member 11 and the application electrode 12 of the plasma actuators 10 adjacently positioned are directly overlapped, and the supporting member 14 of the plasma actuator 10 in +X direction is not provided. Therefore, the plasma induced flow F generated by the surface cleaning devices adjacently positioned can be made flow serially. With this configuration, the shape of the processing space 24 can be simplified. In addition, the sealing level of the processing space 24 can be increased. As a result, it is possible to suppress the active species from leaking out to the outer side on the way of flowing.

### Second Modification

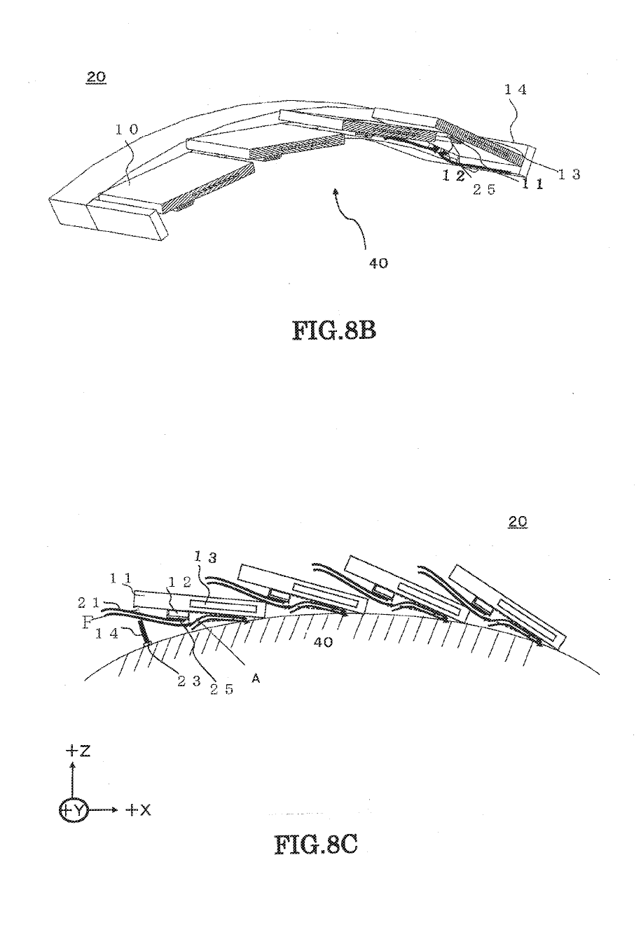

FIG. 8A is a perspective view of a second modification of the surface cleaning device according to the fourth embodiment. FIG. 8B is an enlarged view of the cross section taken along line B-B′ of FIG. 8A. FIG. 8C is a diagram illustrating the cross section taken along line B-B′ of FIG. 8A when viewed in a direction of arrow (+Y direction). As illustrated in FIG. 8A, the processing object having a curved surface can be cleaned by adjusting an overlapping way of the surface cleaning devices. At this time, as illustrated in FIGS. 8B and 8C, the atmosphere can be taken into each of the plasma actuators 10 from the outer side. In addition, as illustrated in FIG. 7, the electrode members 11 of the surface cleaning devices 20 adjacently positioned, or the electrode member 11 and the application electrode 12 thereof, can be directly overlapped. With this configuration, the plasma induced flow F generated by the plasma actuators 10 adjacently positioned can be flown serially without providing the supporting member 14 in +X direction of the plasma actuator 10 (inclined toward a side of +X direction).

In the surface cleaning device according to the fourth embodiment, the application electrode 12 and the processing object 40 can be disposed near, and Plasmas A generated in the plasma actuators 10 adjacently positioned can be disposed near. Therefore, an operation region of the OH radicals can be dense with respect to the processing object 40, and the OH radicals having a short life span contained in the Plasma A can directly act on the processing object 40. As a result, it is possible to clean the processing object with efficiency.

### Fifth Embodiment

The same portions as those of the second embodiment will be omitted.

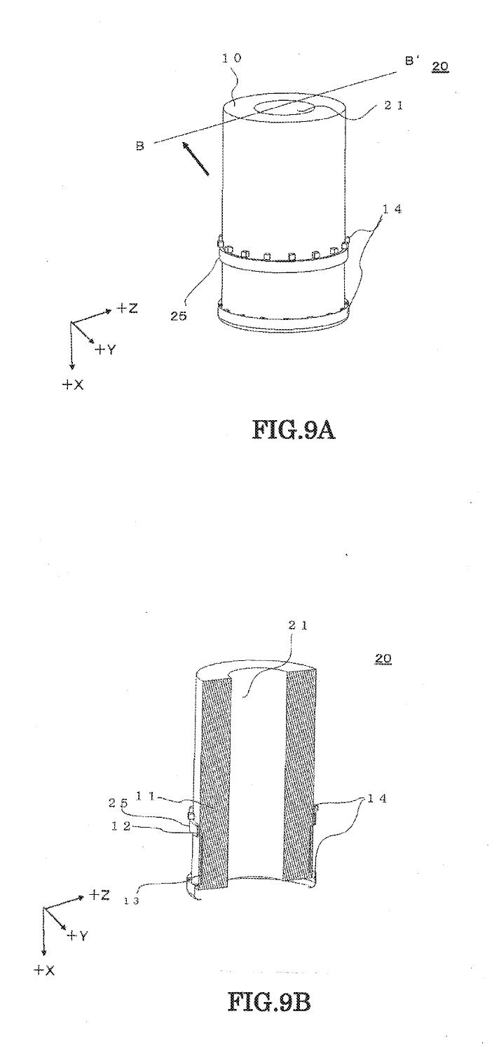

FIG. 9A is a perspective view of the surface cleaning device according to a fifth embodiment. FIG. 9B is a cross-sectional view taken along line B-B′ of FIG. 9A. FIG. 9C is a diagram illustrating the cross section taken along line B-B′ of FIG. 9A when viewed in a direction of arrow. As illustrated in FIG. 9A, in the fifth embodiment, two or more surface cleaning devices are disposed such that surfaces (for example, second surface) on the opposite side of surfaces (for example, first surface) of the electrode members 11 (of the plasma actuators 10 described in the first embodiment) facing the processing object 40 are disposed to face each other. With this structure, for example, the processing object having a facing structure such as a groove or a cylinder can be processed on both surfaces at a time. In addition, the second surfaces of the plasma actuators 10 facing may be bonded.

Alternatively, a space is provided to serve as the through hole 21.

In addition, while not illustrated in the drawing, by connecting the plasma actuators 10 facing with the variable connection member 27, a radius of the surface cleaning device 20 may be varied in accordance with a radius of the processing object 40. In addition, by using a mechanism rotating or making the surface cleaning device rotate in an axial direction, Plasma A can act widely on the processing object 40.

As illustrated in FIGS. 9A and 98, the electrode member 11 of the plasma actuator 10 may be machined in a cylindrical shape or a columnar shape as a single surface cleaning device. At this time, the ground electrode 13 and the application electrode 12 provided in the plasma actuator 10 may be one or a plurality of pieces, respectively.

An ozone processing chamber may be provided in the through hole 21, or to be connected from the through hole 21. The exhaust pump 26 can be connected to the ozone processing chamber.

### First Modification

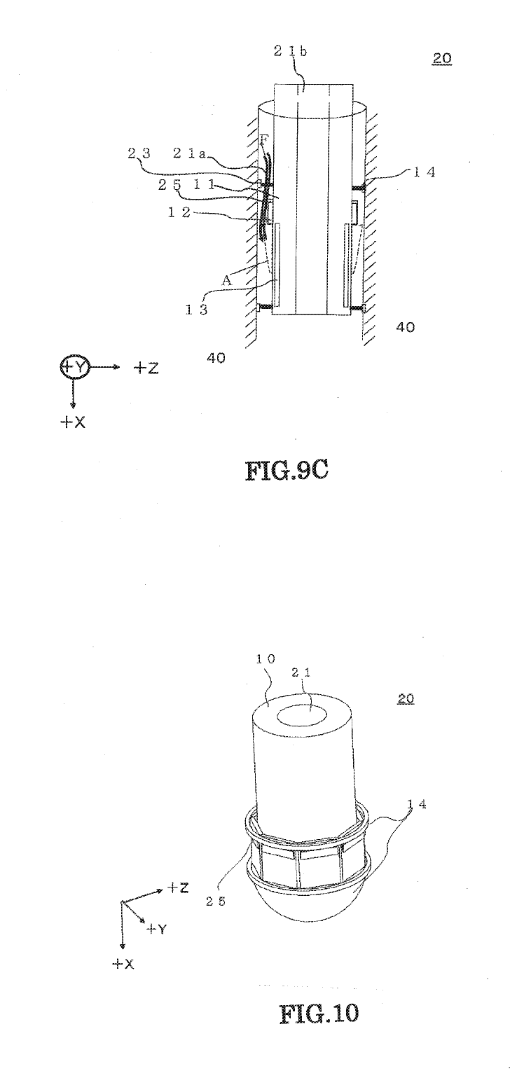

FIG. 10 is a perspective view of a first modification of the surface cleaning device according to the fifth embodiment. As illustrated in FIG. 10, the supporting member 14 on a side near the ground electrode 25 (+X direction) may be shared between the facing plasma actuators 10.

In particular, in a case where the through hole 21 is provided, as illustrated in FIG. 10, the supporting member 14 is disposed to arrange the plasma induced flow F (generated by each plasma actuator 10) toward the through hole 21.

The surface cleaning device according to the fifth embodiment may be used in test tubes or pipes, for example.

In the surface cleaning device according to the fifth embodiment, the application electrode 12 and the processing object 40 can be disposed near, and also the OH radicals having a short life span contained in the Plasma A can directly act on the processing object 40 such as a groove or a cylinder. As a result, it is possible to clean the processing object with efficiency.

As described above, while the OH radicals have a strong redox power and are suitable to the cleaning action, the life span is short to 1 ms. As a distance between the generation region of Plasma A and the processing object is increased, it takes a long time for the OH radicals to reach the processing object. Accordingly, it can be seen that a residual amount of the OH radicals is relatively reduced. As described above, since the plasma is generated from the end of the application electrode at a side near the ground electrode, the residual amount of the OH radicals is reduced as the distance between the application electrode and the processing object increased.

Therefore, it is difficult to make the OH radicals act directly on the processing object with efficiency using a device having a structure of the plasma actuator as the conventional technique.

On the other hand, in any of the surface cleaning devices according to the first to fifth embodiments described above, since the application electrode 12 exists to face the processing object, the Plasma A and the processing object can be disposed near, and the OH radicals can act on the processing object with efficiency. Therefore, it can be seen that all the surface cleaning devices according to the first to fifth embodiments are excellent cleaning devices capable of using the OH radicals directly on the processing object.

According to the surface cleaning device of at least any one of the embodiments described above, the Plasma actuator is configured such that the application electrode 12 faces the processing object. As a result, the Plasma A can be disposed near the processing object, and the OH radicals can act on the processing object with efficiency.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma actuator comprising:
an electrode member having a first surface facing a processing object and a second surface of an opposite side of the first surface;
an application electrode provided in the first surface;
a ground electrode provided in the second surface or an inner portion of the electrode member; and
a supporting member provided in at least one of the electrode member and the application electrode to form a processing space between the processing object and the electrode member,
the supporting member being capable of abutting on the processing object.

2. The plasma actuator according to claim 1, wherein
a plurality of supporting members is provided.

3. A surface cleaning device comprising:
the plasma actuator according to claim 1; and
an AC power source that applies an AC current to the application electrode and the ground electrode,
wherein a plasma is capable of being generated in the processing space.

4. The surface cleaning device according to claim 3, further comprising:
a conduction checking electrode disposed at a portion where the supporting member and the processing object abut to check an insulation state of the processing object.

5. The surface cleaning device according to claim 4, further comprising:
a reception unit that receives a signal from the conduction checking electrode.

6. The surface cleaning device according to claim 3, further comprising:
a through hole provided in the supporting member to pass through an outer side and the processing space.

7. The surface cleaning device according to claim 6, further comprising:
an ozone processing chamber connected to the through hole.

8. The surface cleaning device according to claim 7, further comprising:
an exhaust pump connected to the ozone processing chamber.

9. The surface cleaning device according to claim 3, wherein
at least two plasma actuators are arranged along the processing object, and
a distance between the application electrode of one of two plasma actuators adjacently positioned and the ground electrode of the other of the two plasma actuators adjacently positioned is larger than a distance between the application electrode and the ground electrode of each of the plasma actuators.

10. The surface cleaning device according to claim 9, wherein
each of the plasma actuators is inclined such that a side of the ground electrode approaches the processing object, and is disposed such that two plasma actuators adjacently positioned are partially overlapped.

11. The surface cleaning device according to claim 3, wherein
at least two plasma actuators are arranged along the processing object, and are disposed such that second surfaces of the plasma actuators face each other.

12. The surface cleaning device according to claim 11, further comprising:
a through hole provided in a portion where the second surfaces face each other.

13. The surface cleaning device according to claim 11, wherein
the supporting member abutting on a side of the ground electrode is shared by the plasma actuators.

14. The surface cleaning device according to claim 9, further comprising:
a connection member provided between the two plasma actuators adjacently positioned.

15. A plasma actuator comprising:
an electrode member;
a ground electrode provided in the electrode member;
an application electrode provided in a surface of the electrode member facing a processing object to interpose the electrode member with respect to the ground electrode; and
a supporting member provided in at least one of the electrode member and the application electrode to form a processing space between the processing object and the electrode member,
the supporting member being capable of abutting on the processing object.

16. The plasma actuator according to claim 15, wherein
a plurality of supporting members is provided.

17. A surface cleaning device comprising:
the plasma actuator according to claim 15; and
an AC power source that applies an AC current to the application electrode and the ground electrode,
wherein a plasma is capable of being generated in the processing space.

18. The surface cleaning device according to claim 17, wherein
at least two plasma actuators are arranged along the processing object, and
a distance between the application electrode of one of two plasma actuators adjacently positioned and the ground electrode of the other of the two plasma actuators adjacently positioned is larger than a distance between the application electrode and the ground electrode of each of the plasma actuators.

19. The surface cleaning device according to claim 18, wherein
each of the plasma actuators is inclined such that a side of the ground electrode approaches the processing object, and is disposed such that two plasma actuators adjacently positioned are partially overlapped.

20. A surface cleaning device, comprising:
a plasma actuator including
an electrode member,
a ground electrode provided in the electrode member,
an application electrode provided in a surface of the electrode member facing a processing object to interpose the electrode member with respect to the ground electrode;
a support member capable of abutting on the plasma actuator and the processing object to form a processing space between the plasma actuator and the processing object; and
an AC power source that applies an AC current to the application electrode and the ground electrode.
